(19) United States
(12) Patent Application Publication
(10) Pub. No.: US 2024/0161957 A1
(43) Pub. Date: May 16, 2024

(54) INDUCTOR STRUCTURE AND MANUFACTURING METHOD THEREOF

(71) Applicant: PHOENIX PIONEER TECHNOLOGY CO., LTD., Hsinchu County (TW)

(72) Inventors: Pao-Hung CHOU, Hsinchu County (TW); Shih-Ping HSU, Hsinchu County (TW); Chu-Chin HU, Hsinchu County (TW)

(73) Assignee: PHOENIX PIONEER TECHNOLOGY CO., LTD., Hsinchu County (TW)

(21) Appl. No.: 18/498,128

(22) Filed: Oct. 31, 2023

(30) Foreign Application Priority Data
Nov. 16, 2022 (TW) 111143780

(51) Int. Cl. H01F 17/00; H01F 27/40; H01F 41/04

(52) U.S. Cl. CPC H01F 17/0006; H01F 27/40; H01F 41/041; H01F 2017/0066; H01F 2017/0073; H01L 24/16; H01L 28/10; H01L 2224/16227

(57) ABSTRACT

Provided is an inductor structure and manufacturing method thereof, including forming an inductance coil in a semiconductor packaging carrier plate and disposing a patterned magnetic conductive layer in the inductance coil. Therefore, a patterned build-up wiring method is used to form a magnetic material in the carrier plate, thereby improving electrical characteristics of the inductor.

### BACKGROUND

### 1. Technical Field

The present disclosure relates to an inductor structure, and more particularly, to an inductor structure with a magnetic conductor embedded in a carrier plate.

### 2. Description of Related Art

In recent years, handheld and wearable electronic products have become popular and are constantly developing towards multi-function, thinness, compactness and high integration. Under the needs of these applications, active elements and passive elements used are required to be miniaturized and modularized to improve performance and reduce costs.

In order to achieve the above purpose, in the prior art, passive elements (such as inductors, capacitors and resistors) are often integrated into semiconductor packages in the form of independent elements and chips (embedded methods may also be used). However, when passive elements such as inductive elements require higher electrical characteristics (such as inductance value and Q value), most of them adopt mechanical wire winding embodiments, and their miniaturization has many limitations. Therefore, integrating passive elements into semiconductor packages is not only difficult to meet the miniaturization requirements, but also the embedded method is also a difficult manufacturing process.

Therefore, how to overcome the various problems of the above-mentioned prior art has become an urgent issue in the industry.

### SUMMARY

In view of the problems of the prior art, the present disclosure provides an inductor structure and a manufacturing method thereof, which can at least partially solve the problems of the prior art.

The inductor structure of the present disclosure comprises: a carrier plate having a first side and a second side opposing the first side and a plurality of insulating layers; at least one inductance coil embedded in the carrier plate and comprising a plurality of columnar inductance layers and a plurality of inductance wirings; a conductive wiring structure embedded in the carrier plate, partially electrically connected to the inductance coil and comprising a plurality of first electrode pads provided on the first side and with one surface of each of the plurality of first electrode pads exposed on the first side and a plurality of second electrode pads provided on the second side and with one surface of each of the plurality of second electrode pads exposed on the second side; and a magnetic conductor embedded in a coil of the inductance coil in the carrier plate, wherein the magnetic conductor comprises a magnetic material and at least one patterned magnetic conductive layer.

In the aforementioned inductor structure, the patterned magnetic conductive layer extends to an outside of the inductance coil and has a plurality of openings corresponding to the plurality of columnar inductance layers of the inductance coil, and the plurality of columnar inductance layers pass through the corresponding openings respectively.

In the aforementioned inductor structure, the at least one patterned magnetic conductive layer is a plurality of patterned magnetic conductive layers stacked at intervals in a layered manner.

In the aforementioned inductor structure, the magnetic conductor is in a flat plate shape, a gear shape, a fin shape or a combination thereof.

In the aforementioned inductor structure, shapes of the plurality of columnar inductance layers of the inductance coil are cylinders, rectangles or triangles.

In the aforementioned inductor structure, the inductance coil is a spiral coil, a solenoid coil or a toroid coil.

In the aforementioned inductor structure, the inductor structure is a single discrete element or a discrete element formed by a plurality of inductance integrals.

In the aforementioned inductor structure, the inductor structure is a part of a packaging carrier plate structure with an embedded inductor.

The present disclosure also provides a method of manufacturing an inductor structure. The method comprises: providing a carrier board having a metal surface; forming a plurality of insulating layers and a first conductive wiring structure on the carrier board in a patterned build-up manner, wherein the first conductive wiring structure comprises a plurality of first electrode pads; forming a first inductance layer and a columnar inductance layer of an inductance coil on the first conductive wiring structure and one of the insulating layers using a build-up wiring manufacturing method, and covering the first inductance layer and the columnar inductance layer by another insulating layer; forming a magnetic conductor and another columnar inductance layer of the inductance coil on the another insulating layer, wherein the magnetic conductor comprises a magnetic material and at least one patterned magnetic conductive layer; covering the magnetic conductor and the another columnar inductance layer by other insulating layers; forming a second inductance layer of the inductance coil on the other insulating layers by a build-up wiring manufacturing method, and surrounding the magnetic conductor by the inductance coil; forming a second conductive wiring structure on the other insulating layers and the second inductance layer in a patterned build-up manner, wherein the second conductive wiring structure comprises a plurality of second electrode pads; and removing the carrier board to expose one surface of each of the plurality of first electrode pads of the first conductive wiring structure.

In the aforementioned method, the present disclosure further comprises repeating processes of the magnetic conductor, the columnar inductance layer and the other insulating layers at least once before forming the second inductance layer to form a plurality of patterned magnetic conductive layers stacked at layered intervals.

In the aforementioned method, the columnar inductance layer of the inductance coil is formed by electroplating in any shape.

In the aforementioned method, the inductor structure is completed while preparing a packaging carrier plate.

In the aforementioned inductor structure and method thereof, the patterned magnetic conductive layer is divided vertically and arranged at column-like intervals into a plurality of convex strip structures, divided horizontally and arranged at row-like intervals into a plurality of gear strip structures or grid-divided and arranged at matrix intervals into a plurality of bump structures.

In the aforementioned inductor structure and method, the magnetic conductor comprises a magnetic material. For example, the magnetic material comprises at least one of iron, nickel, cobalt, manganese, zinc, molybdenum or an alloy material of a combination thereof, and the alloy material is nickel/iron alloy, nickel/cobalt alloy, nickel/iron/cobalt alloy or zinc/nickel alloy.

In the aforementioned inductor structure and method, the present disclosure further comprises after removing the carrier board, electrically combining and packaging at least one active chip and/or a passive element on the plurality of first electrode pads, and correspondingly combining a plurality of conductive elements on the plurality of second electrode pads.

As can be seen from the above, in the inductor structure of the present disclosure, a printed circuit board (PCB) or a carrier plate is used to make patterned build-up wirings, and the magnetic material is electroplated or deposited on the carrier plate to form a magnetic conductor, such that the accuracy of the magnetic conductor can be controlled extremely well. Therefore, compared with the prior art, the inductor structure of the present disclosure has excellent precision control of the inductance value. In addition, since the inductor element can be embedded in the carrier plate, the production process can be reduced to reduce the cost. Moreover, because tiny inductive elements can be manufactured, the purpose of miniaturization or thinning of products can be achieved.

Moreover, by utilizing the IC carrier plate process, the inductance coil is designed in the carrier plate at the same time, such that the packaging carrier plate has an inductance function, and no additional inductive elements are required to be prepared during the packaging process. Accordingly, compared with the prior art, the inductor structure of the present disclosure can reduce manufacturing costs.

Further, by means of the design of the multiple-layer patterned magnetic conductive layer, the inductance value can be increased and the influence of the eddy current and magnetic loss on a Q value (where Q stands for quality or quality factor) can be reduced.

In addition, compared with an iron core block configuration of prior art, a thickness of the inductor structure of the present disclosure can be adjusted according to needs, thereby making it easier to miniaturize and facilitate the end product to meet the miniaturization requirements.

### BRIEF DESCRIPTION OF THE DRAWINGS

FIG. 1A is a schematic cross-sectional view showing an inductor structure according to the present disclosure.

FIG. 1B is a schematic partial perspective view showing a magnetic conductor of the inductor structure according to another embodiment of the present disclosure.

FIG. 1C is a schematic cross-sectional view showing another embodiment of FIG. 1A.

FIG. 2A is a schematic cross-sectional view showing another embodiment of FIG. 1A.

FIG. 2B is a schematic partial perspective view showing a magnetic conductor of the inductor structure according to another embodiment of the present disclosure.

FIG. 2C is a schematic cross-sectional view showing another embodiment of FIG. 2A.

FIG. 3A, FIG. 3B, FIG. 3C, FIG. 3D-1, FIG. 3E, FIG. 3F, FIG. 3G and FIG. 3H are schematic cross-sectional views showing a method of manufacturing an inductor structure according to the present disclosure.

FIG. 3D-2 is a schematic cross-sectional view showing another embodiment of FIG. 3D-1.

FIG. 4A is a schematic cross-sectional view showing the subsequent process of FIG. 3H.

FIG. 4B is a schematic cross-sectional view showing the application of FIG. 2A.

FIG. 5A to FIG. 5D are schematic perspective views showing different embodiments of the magnetic conductor of the inductor structure according to the present disclosure.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “fourth,” “fifth,” “sixth,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

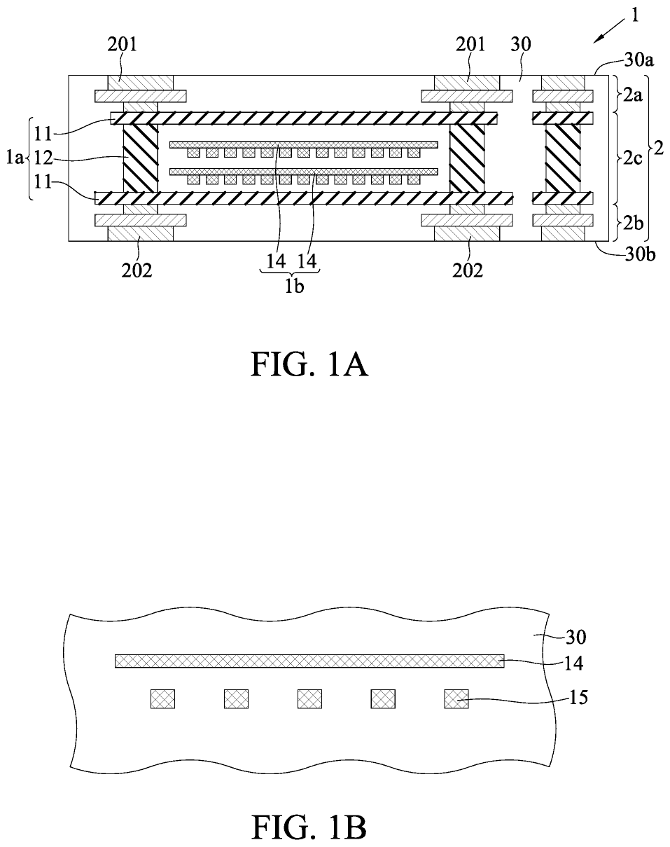

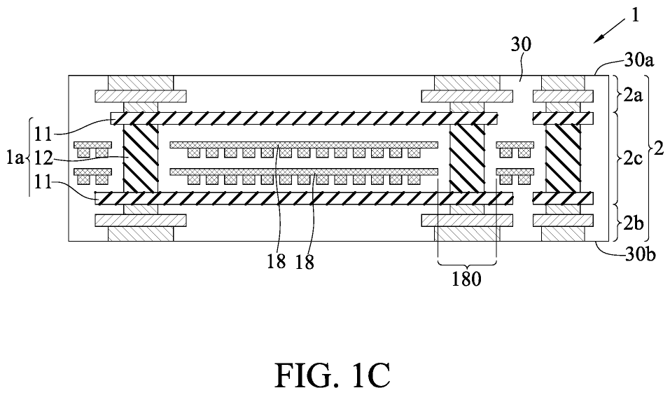

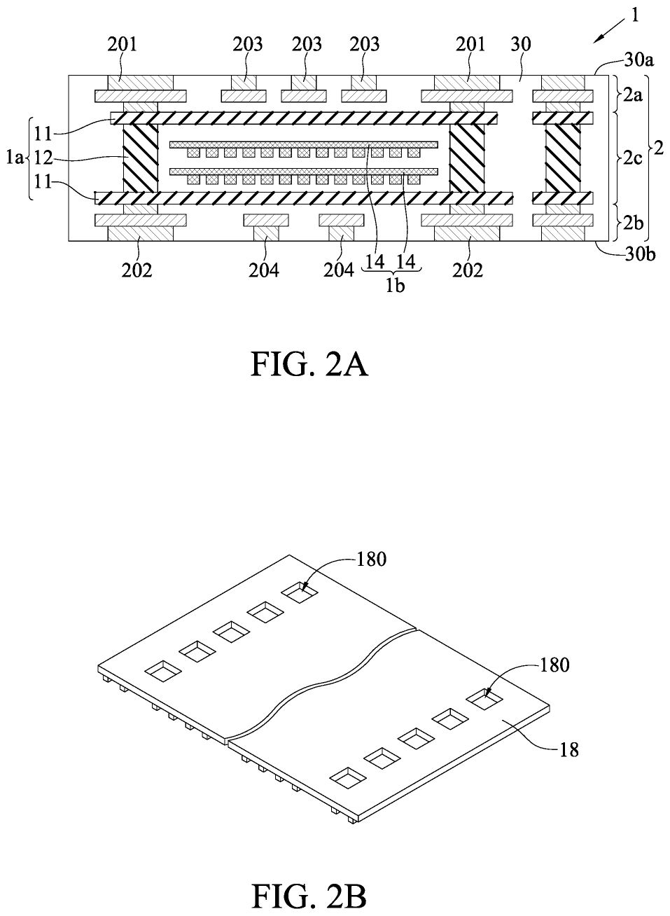

FIG. 1A is a schematic cross-sectional view showing an inductor structure 1 according to the present disclosure. As shown in FIG. 1A, the inductor structure 1 includes a carrier plate 30, at least one inductance coil 1a embedded in the carrier plate 30, a conductive wiring structure 2 embedded in the carrier plate 30 and partially electrically connected to the inductance coil 1a, and a magnetic conductor 1b embedded in the carrier plate 30 and not electrically connected to the inductance coil 1a.

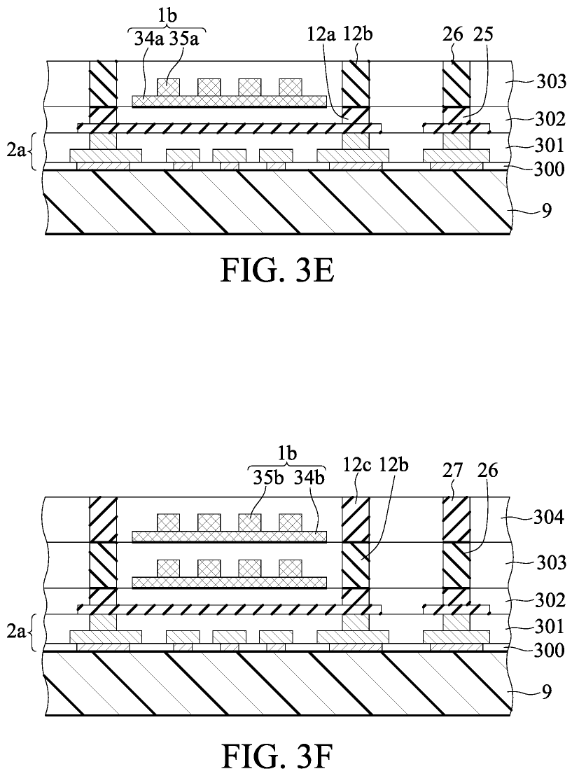

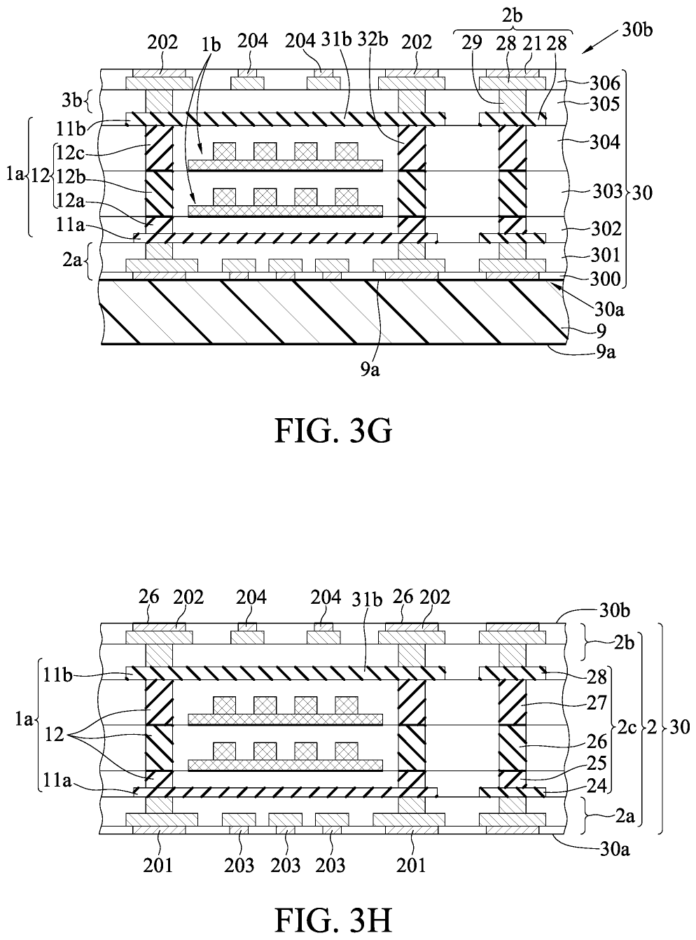

The carrier plate 30 has a first side 30a and a second side 30b opposing the first side 30a, which serve as electrode pad sides. For example, the first side 30a is a chip-mounting side, which is a bonding pad side of an inductor or a chip-mounting side of a packaging carrier plate. The second side 30b is a bonding pad side, and the carrier plate 30 includes a plurality of insulating layers (such as a first insulating layer 301, a second insulating layer 302, a third insulating layer 303, a fourth insulating layer 304, a fifth insulating layer 305, a sixth insulating layer 306 and an insulating protective layer 300 as shown in FIG. 3H).

In an embodiment, the insulating layers of the carrier plate 30 are made of a photosensitive or non-photosensitive dielectric material, Ajinomoto Build-up Film (ABF), polyimide (PI), epoxy molding compound/resin (EMC), flame resistance/retardant 4 (FR4) or flame resistance/retardant 5 (FR5) containing glass fiber, bismaleimide triazine (BT) or other appropriate materials.

The conductive wiring structure 2 includes a first conductive wiring structure 2a, a second conductive wiring structure 2b and a conductive structure 2c. The first conductive wiring structure 2a includes a plurality of first electrode pads 201 provided on the first side 30a and with one surface of each of the first electrode pads 201 exposed on the first side 30a. In addition, the second conductive wiring structure 2b includes a plurality of second electrode pads 202 provided on the second side 30b and with one surface of each of the second electrode pads 202 exposed on the second side 30b. The conductive structure 2c vertically conducts the first conductive wiring structure 2a and the second conductive wiring structure 2b to electrically connect the first conductive wiring structure 2a and the second conductive wiring structure 2b.

In an embodiment, the electrode pads (such as the first electrode pads 201 and the second electrode pads 202) of the conductive wiring structure 2 serve as bonding pads which are used to externally connect electronic elements or circuit boards. The bonding pads may be provided on one side or both sides.

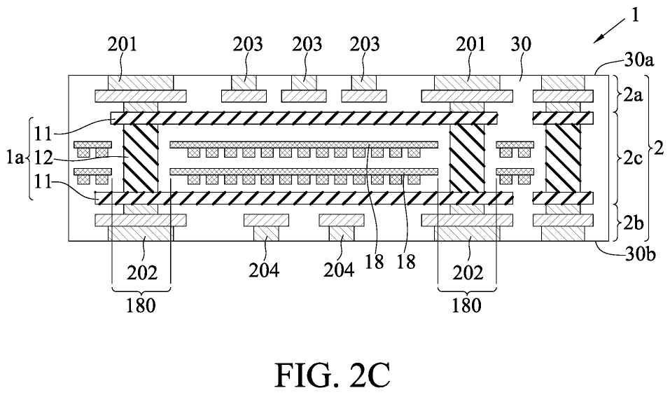

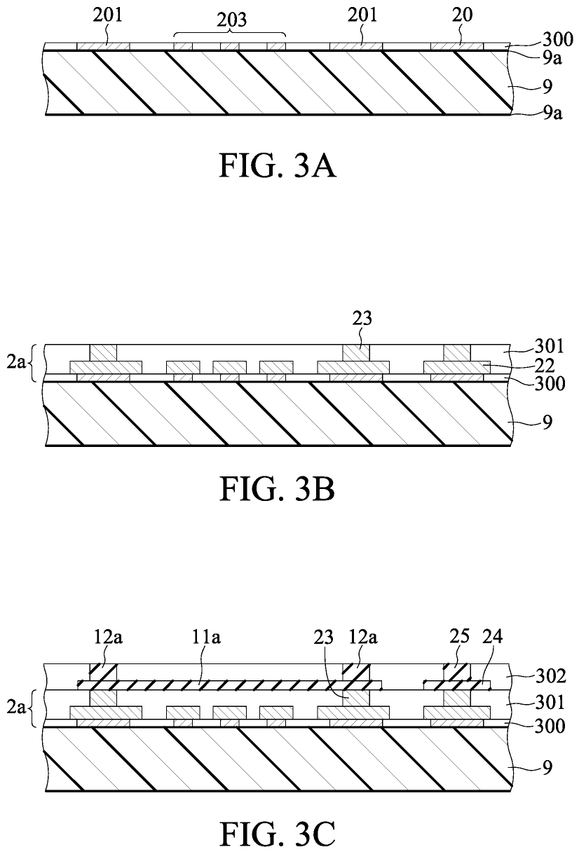

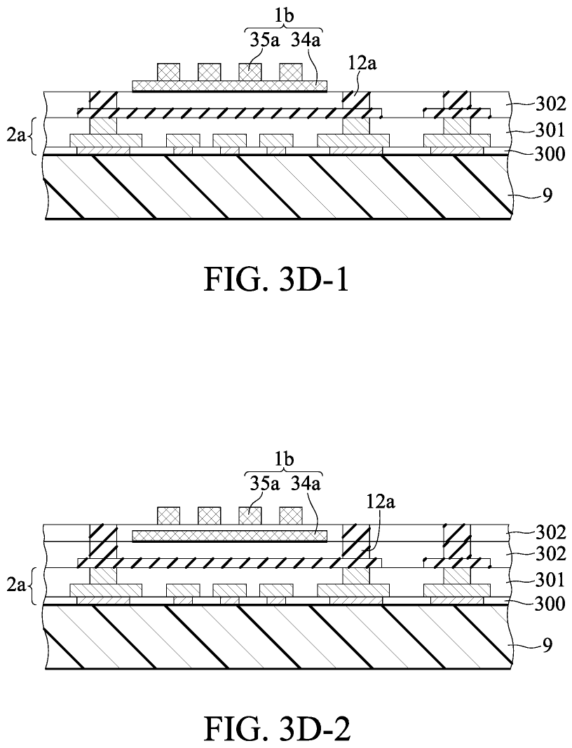

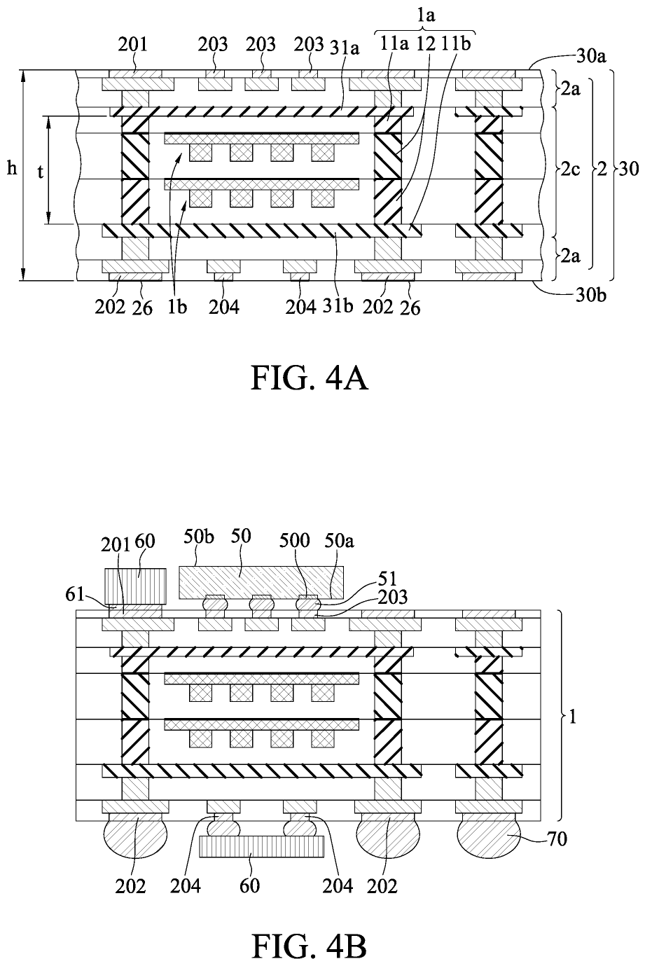

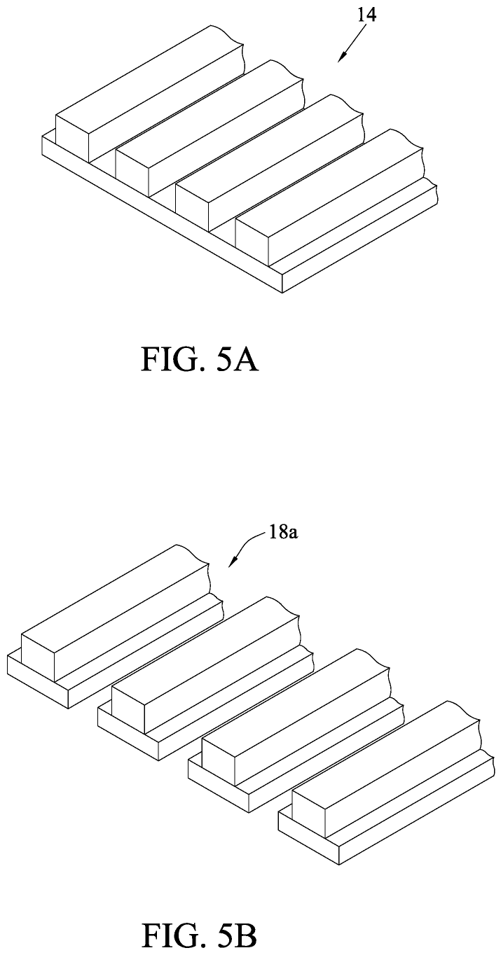

Moreover, in another embodiment, the inductor structure 1 shown in FIG. 2A has an inductor embedded in a carrier plate structure for semiconductor packaging. For example, the first conductive wiring structure 2a on the first side 30a of the carrier plate 30 also includes a plurality of first electrode pads 203 for packaging bonding (such as flip chip or wire bonding) to define the first side 30a as a bonding pad side of an inductor or a chip-mounting side of a packaging carrier plate. In addition, the second side 30b is a bonding pad side, such that the second electrode pads 202, 204 are used as bonding pads to connect external elements (such as solder balls, passive elements, active elements or circuit boards). As shown in FIG. 4B, the plurality of first electrode pads 203 are electrically connected to a passive element 60 (e.g., a capacitive element) and/or a flip-chip active chip 50.

In addition, a surface treatment layer (not shown) may be formed on the first electrode pads 201, 203 and the second electrode pads 202, 204 to facilitate the connection of electronic elements, wherein a material of forming the surface treatment layer (not shown) is nickel/gold (Ni/Au), nickel/palladium/gold (Ni/Pd/Au), solder materials, organic solderability preservative (OSP) or combinations thereof, etc. Besides, an outermost insulating layer on the second side 30b (or the first side 30a) of the carrier plate 30 may serve as an insulating protective layer and the electrode pads (or the surface treatment layer thereon) are exposed from the insulating protective layer, wherein a material of forming the insulating protective layer (not shown) is a dielectric material, a photosensitive or non-photosensitive organic insulating material, such as solder resist, PI, ABF and EMC, etc.

The inductance coil 1a is embedded in the carrier plate 30 and includes a single-layer inductance wiring 11 or multiple-layer inductance wirings 11 (e.g., two layers) stacked at intervals in a layered manner and embedded in the carrier plate 30, and a columnar inductance layer 12 connected between the inductance wirings 11.

In an embodiment, the inductance coil 1a is a spiral coil, a solenoid coil or a toroid coil, and a shape of the columnar inductance layer 12 is a cylinder, a rectangle or a triangle.

The magnetic conductor 1b is formed in a coil of the inductance coil 1a in the carrier plate 30, wherein the magnetic conductor 1b includes at least one patterned magnetic conductive layer 14.

In an embodiment, the magnetic conductor 1b is made by electroplating, electroless plating, sputtering, physical vapor deposition (PVD) or chemical vapor deposition (CVD), etc., and the magnetic conductor 1b contains high magnetic permeability material and includes at least one of iron (Fe), nickel (Ni), cobalt (Co), manganese (Mn), zinc (Zn), molybdenum (Mo) or an alloy material of a combination thereof, such as nickel/iron alloy, nickel/cobalt alloy, cobalt/nickel/iron alloy, zinc/nickel alloy or other alloys, or other magnetic substances, etc.

Further, the single patterned magnetic conductive layer 14 of the magnetic conductor 1b is a flat-shaped plate, a gear-shaped plate or a fin-shaped plate. Alternatively, the magnetic conductor 1b may include a plurality of the patterned magnetic conductive layers 14 stacked at intervals in a layered manner. As shown in FIG. 1B, even the magnetic conductor 1b may be composed of the patterned magnetic conductive layers 14, 15 that are separated from each other. The purpose of the magnetic conductor 1b is to reduce eddy current effects and magnetic losses, thereby improving electrical characteristics of inductance.

In addition, a patterned magnetic conductive layer 18 may have at least one opening 180. As shown in FIG. 1C, FIG. 2B and FIG. 2C, the patterned magnetic conductive layer 18 extends to an outside of the inductance coil 1a, and the magnetic conductor 1b has corresponding openings 180 at the columnar inductance layers 12 of the inductance coil 1a, such that each of the columnar inductance layers 12 passes through each of the openings 180.

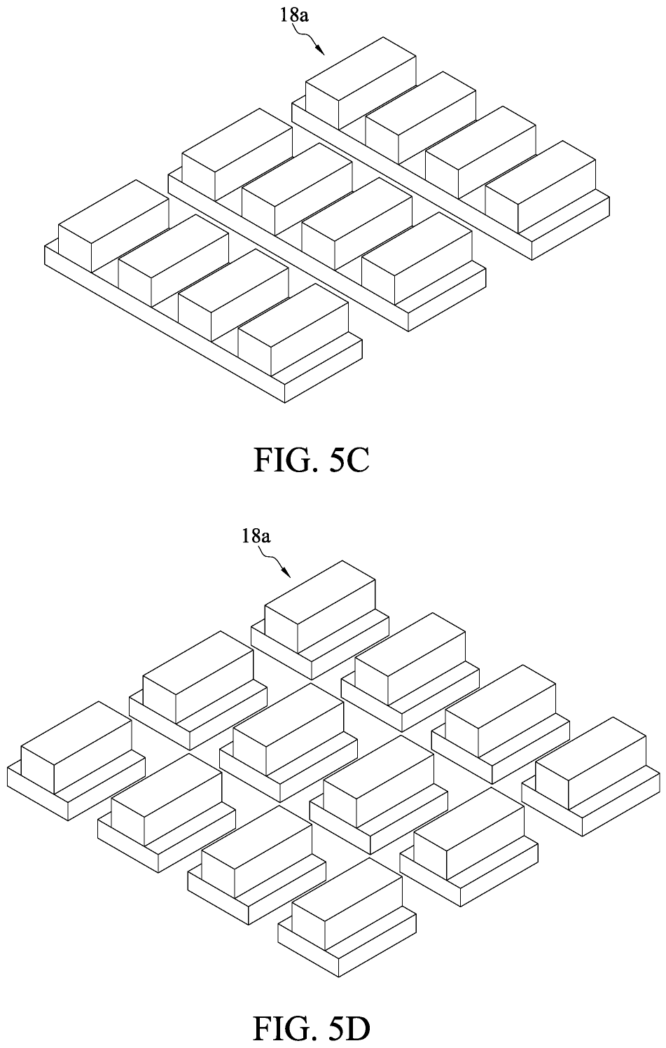

Additionally, a patterned magnetic conductive layer 18a is divided vertically and arranged at column-like intervals into a plurality of convex strip structures (as shown in FIG. 5B), divided horizontally and arranged at row-like intervals into a plurality of gear strip structures (as shown in FIG. 5C) or grid-divided and arranged at matrix intervals into a plurality of bump structures (as shown in FIG. 5D).

FIG. 3A, FIG. 3B, FIG. 3C, FIG. 3D-1, FIG. 3E, FIG. 3F, FIG. 3G and FIG. 3H are schematic cross-sectional views showing a method of manufacturing the inductor structure 1 according to the present disclosure.

As shown in FIG. 3A to FIG. 3B, the first conductive wiring structure 2a (including the plurality of first electrode pads 201, 203) is formed on a carrier board 9 having a metal surface by using a build-up wiring manufacturing method, and at least one insulating layer (e.g., the insulating protective layer 300 and the first insulating layer 301) are formed on the carrier board 9 to cover the first electrode pads 201, 203.

In an embodiment, the carrier board 9 is a combination of a removable metal plate and an insulating material, and the carrier board 9 may also be a copper foil substrate, but the present disclosure is not limited to as such. There is a metal material 9a having thin copper (thickness about 0.5 microns to 10 microns) on both sides of the carrier board 9.

According to the present disclosure, a method of manufacturing the inductor structure 1 adopts the build-up technology of the semiconductor packaging carrier plate and selects a process with a core layer or a coreless layer. This embodiment is illustrated with a build-up technology having a coreless layer, that is, a patterned wiring build-up is formed on the carrier board 9. For instance, patterned wirings or conductive pillars are first formed on the carrier board 9, subsequently an insulating layer is formed (by vacuum lamination or coating), and then the surfaces of the conductive pillars are exposed on the insulating layer by grinding. In addition, a semi-additive process (referred to as SAP) is used to form a seed layer on the insulating layer for electroplating patterned wiring, and a build-up wiring structure is formed by removing photoresist and rapidly etching the excess seed layer. By repeating the steps in this method, a multilayer build-up can be formed. The conductive wiring structure 2, the inductance coil 1a and the magnetic conductor 1b of the present disclosure can all be processed by this method. Besides, the conductive pillars can also be replaced by laser blind holes, which will not be described again.

Further, a first wiring layer 20, conductive wirings 22 and conductive pillars 23 of the first conductive wiring structure 2a are formed in a patterned build-up manner to enable the conductive wirings 22 to be partially electrically connected to the first electrode pads 201, 203 of the first wiring layer 20, and the conductive pillars 23 are formed on the conductive wirings 22, and the upper surfaces of the conductive pillars 23 are exposed from the first insulating layer 301. For example, the insulating protective layer 300 encases the first wiring layer 20, and the first insulating layer 301 encases the conductive wirings 22 and the conductive pillars 23.

As shown in FIG. 3C, a first inductance layer 11a is formed on the first insulating layer 301, part of the first inductance layer 11a is connected to part of the conductive pillars 23, and then first columnar inductance layers 12a are formed on the first inductance layer 11a, such that a position of the first columnar inductance layer 12a is connected to a position of part of the first inductance layer 11a. Next, the second insulating layer 302 is formed on the first insulating layer 301 to enclose the first inductance layer 11a and the first columnar inductance layers 12a, and the first columnar inductance layers 12a are exposed from the second insulating layer 302. In forming the first inductance layer 11a and the first columnar inductance layer 12a, a vertical conductive layer is simultaneously formed and contains a conductive wiring 24 and a conductive pillar 25 stacked on the conductive wiring 24, such that the second insulating layer 302 encases the conductive wiring 24 and the conductive pillar 25, and the conductive pillar 25 is exposed from the second insulating layer 302.

In an embodiment, the materials of the inductance layers are copper (Cu), copper alloys, nickel (Ni), silver (Ag), other conductors or a combination thereof.

As shown in FIG. 3D-1, a patterned first magnetic conductive layer 34a is formed on the second insulating layer 302, and the first magnetic conductive layer 34a is not in contact with the exposed surfaces of the first columnar inductance layers 12a, and then a gear-shaped magnetic conductive layer 35a is formed on the first magnetic conductive layer 34a to enable the first magnetic conductive layer 34a and the gear-shaped magnetic conductive layer 35a to act as the magnetic conductor 1b, wherein the gear-shaped magnetic conductive layer 35a is combined with the first magnetic conductive layer 34a to form a fin, or the first magnetic conductive layer 34a is separated from the gear-shaped magnetic conductive layer 35a by another second insulating layer 302 (as shown in FIG. 3D-2).

In an embodiment, the first magnetic conductive layer 34a and the gear-shaped magnetic conductive layer 35a may be made by electroplating, electroless plating, sputtering, physical vapor deposition (PVD) or chemical vapor deposition. (CVD), etc.

Furthermore, the structure design of the magnetic conductor 1b may be in the form of a continuous or non-continuous thin sheet depending on the demand, such as a complete shaped continuous thin sheet as shown in FIG. 5A, a longitudinally cut non-continuous thin sheet (or a plurality of mutually separated strips) as shown in FIG. 5B, a transversely cut non-continuous thin sheet (or a plurality of mutually separated strips) as shown in FIG. 5C, and longitudinally and transversely split non-continuous thin sheets (or a plurality of mutually separated blocks) as shown in FIG. 5D.

As shown in FIG. 3E, a second columnar inductance layer 12b is formed on the second insulating layer 302 in a patterned build-up manner, and the second columnar inductance layer 12b is connected to the first columnar inductance layer 12a to subsequently vertically conductively connect a second inductance layer 11b. Next, the third insulating layer 303 is formed to encase the second columnar inductance layer 12b, the first magnetic conductive layer 34a and the gear-shaped magnetic conductive layer 35a thereon, and the second columnar inductance layer 12b is exposed to the third insulating layer 303. At the same time, a vertical conductive layer is formed, which includes a plurality of conductive pillars 26 stacked on the conductive pillars 25, such that the third insulating layer 303 encases the conductive pillars 26, and the conductive pillars 26 are exposed from the third insulating layer 303.

As shown in FIG. 3F, the above steps are repeated to form a second magnetic conductive layer 34b on the third insulating layer 303 and a gear-shaped magnetic conductive layer 35b on the second magnetic conductive layer 34b. Subsequently a third columnar inductance layer 12c is formed, and the fourth insulating layer 304 is formed on the third insulating layer 303 to encase the third columnar inductance layer 12c, the second magnetic conductive layer 34b and the gear-shaped magnetic conductive layer 35b thereon. In addition, the third columnar inductance layer 12c is exposed from the fourth insulating layer 304. At the same time, a vertical conductive layer is formed, which includes a plurality of conductive pillars 27 stacked on the conductive pillars 26, such that the fourth insulating layer 304 encases the conductive pillars 27, and the conductive pillars 27 are exposed from the fourth insulating layer 304.

In an embodiment, the gear shapes of the gear-shaped magnetic conductive layers 35a, 35b may be circular, rectangular, triangular conical or U-shaped, and may be designed to vary in thickness or height.

Furthermore, the gear-shaped magnetic conductive layers 35a, 35b may also be spaced apart from the first magnetic conductive layer 34a or the second magnetic conductive layer 34b. For example, only the first magnetic conductive layer 34a (omitting the gear-shaped magnetic conductive layer 35a) is made below, and only the gear-shaped magnetic conductive layer 35b (omitting the second magnetic conductive layer 34b) is made above.

As shown in FIG. 3G, the second inductance layer 11b is formed on the fourth insulating layer 304 to be electrically connected to the third columnar inductance layer 12c. Next, the second conductive wiring structure 2b is formed on the second inductance layer 11b to electrically connect the second inductance layer 11b. The second conductive wiring structure 2b includes the plurality of second electrode pads 202, 204, and the fifth insulating layer 305 and the sixth insulating layer 306 encase the second inductance layer 11b and the second conductive wiring structure 2b to form the carrier plate 30 having a plurality of insulating layers, wherein the carrier plate 30 has the first side 30a and the second side 30b opposing the first side 30a for use as electrode pad sides.

In an embodiment, a second wiring layer 21, a conductive wiring 28 and a conductive pillar 29 of the second conductive wiring structure 2b are formed in a patterned build-up manner. In addition, the sixth insulating layer 306 serves as an insulating protective layer, and the first side 30a serves as a bonding pad side of the inductor or a chip-mounting side of the packaging carrier plate, and the second side 30b serves as a bonding pad side.

Further, the first inductance layer 11a, the second inductance layer 11b, the first columnar inductance layer 12a, the second columnar inductance layer 12b and the third columnar inductance layer 12c form the coil-shaped inductance coil 1a, and the inductance coil 1a is embedded in the carrier plate 30.

In addition, the first magnetic conductive layer 34a, the second magnetic conductive layer 34b and the gear-shaped magnetic conductive layers 35a, 35b thereon constitute the magnetic conductor 1b, which is embedded in the coil of the inductance coil 1a in the carrier plate 30 without electrically connecting the inductance coil 1a.

Additionally, the first columnar inductance layer 12a, the second columnar inductance layer 12b and the third columnar inductance layer 12c are formed by electroplating in any shape, which may be cylinder, rectangular, triangular or other geometrical shapes, and may be adjusted according to design requirements to reduce the resistance value.

As shown in FIG. 3H, a surface treatment layer (not shown) is formed on the exposed surfaces of the second electrode pads 202, 204 and/or the exposed surfaces of the first electrode pads 201, 203, and the first conductive wiring structure 2a and the second conductive wiring structure 2b together with the vertical conductive structure 2c serve as the conductive wiring structure 2 and are partially electrically connected to the first inductance layer 11a and the second inductance layer 11b of the inductance coil 1a. Next, the carrier board 9 is removed to expose the first side 30a of the carrier plate 30, after which it can be flipped (as shown in FIG. 4A) to obtain a carrier plate structure equivalent to the inductor structure 1 shown in FIG. 1A or the inductance-embedded semiconductor package of FIG. 2A.

In an embodiment, the conductive wirings 24, 28 and the conductive pillars 25, 26, 27 form the vertical conductive structure 2c.

Therefore, the inductor structure 1 of the present disclosure is designed as an inductance coil (e.g., the inductance coil 1a) by utilizing the design of the conductive wiring structure 2 and the change in the dielectric material properties during the production of the packaging carrier plate, and an alloy metal material with high magnetic permeability (e.g., the magnetic conductor 1b) is electroplated in the inductance coil 1a in order to obtain an inductive element (i.e., the combination of the inductance coil 1a and the magnetic conductor 1b) with a large magnetic flux (i.e., in compliance with the demand for larger inductance value or thinness). Consequently, the inductive element is completed with the simultaneous production of a general signal-conducting wiring structure in the packaging carrier plate.

It should be appreciated that only the inductive element can be manufactured by the process of packaging carrier plate without the need to manufacture the conductive wiring structure 2, so as to obtain a flat/thin inductive element (or electromagnetic element), the overall size/thickness of which can be reduced to approximately 0.2 mm to achieve the purpose of miniaturization or thinning of products.

In the subsequent process, the passive element 60 such as a capacitive element and/or the active chip 50 may be electrically combined and packaged on the plurality of first electrode pads 201, 203, as shown in FIG. 4B, and a conductive element 70, such as a solder ball, may be correspondingly bonded to a portion of the second electrode pad 202 exposed on the second side 30b of the carrier plate 30, as shown in FIG. 4B, and another passive element 60 may be electrically bonded and packaged on a portion of the second electrode pad 204.

In an embodiment, the active chip 50 is a semiconductor chip having an active surface 50a and an inactive surface 50b opposing the active surface 50a. The active surface 50a has a plurality of contacts 500 to bond to a plurality of solder bumps 51 invertedly bonded to the first electrode pads 203 with a smaller end surface. Alternatively, the capacitive element is the passive element 60, which is bonded onto the first electrode pad 201 with a larger end surface via a conductive layer 61.

In summary, the inductor structure 1 of the present disclosure is manufactured by adopting the carrier plate processing method, in order to easily carry out the mass production of the large board surface, and adopts a patterned build-up wiring manufacturing method of the coreless embodiment to form the magnetic material by electroplating or deposition. Therefore, compared to the prior art, the inductor structure 1 of the present disclosure can reduce the production process because it is embedded in the carrier plate to reduce the cost, and can be miniaturized or thinner because it can be fabricated with tiny inductive elements.

Furthermore, by utilizing the IC carrier plate process, the inductance coil 1a is designed in the carrier plate 30, such that the packaging carrier plate has an inductive function, and there is no need to prepare additional inductive elements during the packaging process.

In addition, the design of the gear-shaped magnetic conductive layers 35a, 35b can increase the cross-sectional area, increase the inductance value, and reduce the influence of eddy current and magnetic loss on the Q value.

Besides, compared to the configuration of the iron core block in the prior art, a thickness h (or a distance t between the first inductance layer 11a and the second inductance layer 11b as shown in FIG. 4A) of the inductor structure 1 of the present disclosure can be adjusted according to the demand without the need to configure the iron core blocks, which is easier to miniaturize, and thus facilitates the end products to comply with the demand for miniaturization. It should be understood that the carrier plate 30 of the inductor structure 1 of the present disclosure is easy to fabricate without doping the magnetic powder, thereby reducing the fabrication cost and facilitating the end product to meet the demand for economic benefits.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An inductor structure, comprising:
a carrier plate having a first side and a second side opposing the first side and a plurality of insulating layers;
at least one inductance coil embedded in the carrier plate and comprising a plurality of columnar inductance layers and a plurality of inductance wirings;
a conductive wiring structure embedded in the carrier plate, partially electrically connected to the inductance coil and comprising a plurality of first electrode pads provided on the first side and with one surface of each of the plurality of first electrode pads exposed on the first side and a plurality of second electrode pads provided on the second side and with one surface of each of the plurality of second electrode pads exposed on the second side; and
a magnetic conductor embedded in a coil of the inductance coil in the carrier plate, wherein the magnetic conductor comprises a magnetic material and at least one patterned magnetic conductive layer.

2. The inductor structure of claim 1, wherein the patterned magnetic conductive layer extends to an outside of the inductance coil and has a plurality of openings corresponding to the plurality of columnar inductance layers of the inductance coil, and the plurality of columnar inductance layers pass through the corresponding openings respectively.

3. The inductor structure of claim 1, wherein the patterned magnetic conductive layer is divided vertically and arranged at column-like intervals into a plurality of convex strip structures, divided horizontally and arranged at row-like intervals into a plurality of gear strip structures or grid-divided and arranged at matrix intervals into a plurality of bump structures.

4. The inductor structure of claim 1, wherein the at least one patterned magnetic conductive layer is a plurality of patterned magnetic conductive layers stacked at intervals in a layered manner.

5. The inductor structure of claim 4, wherein the patterned magnetic conductive layer is divided vertically and arranged at column-like intervals into a plurality of convex strip structures, divided horizontally and arranged at row-like intervals into a plurality of gear strip structures or grid-divided and arranged at matrix intervals into a plurality of bump structures.

6. The inductor structure of claim 1, wherein the magnetic material comprises at least one of iron, nickel, cobalt, manganese, zinc, molybdenum or an alloy material of a combination thereof, and the alloy material is nickel/iron alloy, nickel/cobalt alloy, nickel/iron/cobalt alloy or zinc/nickel alloy.

7. The inductor structure of claim 1, wherein the magnetic conductor is in a flat plate shape, a gear shape, a fin shape or a combination thereof.

8. The inductor structure of claim 1, wherein shapes of the plurality of columnar inductance layers of the inductance coil are cylinders, rectangles or triangles.

9. The inductor structure of claim 1, wherein the inductance coil is a spiral coil, a solenoid coil or a toroid coil.

10. The inductor structure of claim 1, wherein the inductor structure is a single discrete element or a discrete element formed by a plurality of inductance integrals.

11. The inductor structure of claim 1, wherein the inductor structure is a part of a packaging carrier plate structure with an embedded inductor.

12. The inductor structure of claim 1, wherein the plurality of first electrode pads are electrically connected to at least one active chip and/or a capacitive element.

13. A method of manufacturing an inductor structure, the method comprising:
providing a carrier board having a metal surface;
forming a plurality of insulating layers and a first conductive wiring structure on the carrier board in a patterned build-up manner, wherein the first conductive wiring structure comprises a plurality of first electrode pads;
forming a first inductance layer and a columnar inductance layer of an inductance coil on the first conductive wiring structure and one of the insulating layers using a build-up wiring manufacturing method, and covering the first inductance layer and the columnar inductance layer by another insulating layer;
forming a magnetic conductor and another columnar inductance layer of the inductance coil on the another insulating layer, wherein the magnetic conductor comprises a magnetic material and at least one patterned magnetic conductive layer;
covering the magnetic conductor and the another columnar inductance layer by other insulating layers;
forming a second inductance layer of the inductance coil on the other insulating layers by a build-up wiring manufacturing method, and surrounding the magnetic conductor by the inductance coil;
forming a second conductive wiring structure on the other insulating layers and the second inductance layer in a patterned build-up manner, wherein the second conductive wiring structure comprises a plurality of second electrode pads; and
removing the carrier board to expose one surface of each of the plurality of first electrode pads of the first conductive wiring structure.

14. The method of claim 13, wherein the patterned magnetic conductive layer is divided vertically and arranged at column-like intervals into a plurality of convex strip structures, divided horizontally and arranged at row-like intervals into a plurality of gear strip structures or grid-divided and arranged at matrix intervals into a plurality of bump structures.

15. The method of claim 13, further comprising repeating processes of the magnetic conductor, the columnar inductance layer and the other insulating layers at least once before forming the second inductance layer to form a plurality of patterned magnetic conductive layers stacked at layered intervals.

16. The method of claim 15, wherein the patterned magnetic conductive layer is divided vertically and arranged at column-like intervals into a plurality of convex strip structures, divided horizontally and arranged at row-like intervals into a plurality of gear strip structures or grid-divided and arranged at matrix intervals into a plurality of bump structures.

17. The method of claim 13, wherein the columnar inductance layer of the inductance coil is formed by electroplating in any shape.

18. The method of claim 13, wherein the magnetic material comprises at least one of iron, nickel, cobalt, manganese, zinc, molybdenum or an alloy material of a combination thereof, and the alloy material is nickel/iron alloy, nickel/cobalt alloy, nickel/iron/cobalt alloy or zinc/nickel alloy.

19. The method of claim 13, wherein the inductor structure is completed while preparing a packaging carrier plate.

20. The method of claim 13, further comprising after removing the carrier board, electrically combining and packaging at least one active chip and/or a passive element on the plurality of first electrode pads, and correspondingly combining a plurality of conductive elements on the plurality of second electrode pads.
